(19) United States
(12) Patent Application Publication
(10) Pub. No.: US 2025/0096534 A1
(43) Pub. Date: Mar. 20, 2025

(54) HIGH POWER LASER ASSEMBLY WITH ACCURATE POINTING IN THE FAR FIELD

(71) Applicant: Daylight Solutions, Inc., San Diego, CA (US)

(72) Inventors: Alexander Jason Whitmore, San Diego, CA (US); Brian Adam Daniel, Escondido, CA (US); Marcus Daniel Lanovaz, San Diego, CA (US); John Robert Rowlette, Jr., Raleigh, NC (US)

(21) Appl. No.: 18/292,276

(22) PCT Filed: Jul. 14, 2022
(86) PCT No.: PCT/US2022/037073

§ 371 Date: Jan. 25, 2024

Related U.S. Application Data
(60) Provisional application No. 63/225,814, filed on Jul. 26, 2021.

(51) Int. Cl. H01S 5/40; H01S 5/02253

(52) U.S. Cl. CPC H01S 5/4012; H01S 5/02253; H01S 5/4087

(57) ABSTRACT

A laser assembly (10) for generating an output beam (12) includes: (i) a first laser (16) that generates a first laser beam (16A) having a first polarization state; (ii) a second laser (20) that generates a second laser beam (20A); (iii) a polarization beam combiner (24) that combines the first laser beam (16A) and the rotated second laser beam (20A) to form a combination beam (25); and (iv) an optical assembly (32) that expands and collimates the combination beam (25) to provide the output beam (12). The optical assembly (32) include an on-axis telescope plus a projection lens.

### RELATED APPLICATION

This application claims priority on U.S. Provisional Application No. 63/225,814, filed on Jul. 26, 2021, and entitled “HIGH POWER LASER ASSEMBLY WITH ACCURATE POINTING IN THE FAR FIELD”. As far as permitted, the contents of U.S. Provisional Application No. 63/225,814 are incorporated herein by reference.

### BACKGROUND

Laser assemblies are used in many applications, such as test labs, cutting lasers, welding lasers, and other applications. In many applications, important requirements of the laser assembly include maximizing output power, and minimizing pointing errors. There is a never-ending desire to increase the power output, while decreasing the form factor and pointing errors for the laser assembly.

### SUMMARY

The present invention is directed to a laser assembly for generating an output beam. In one implementation, the laser assembly includes: (i) a first laser that generates a first laser beam having a first polarization state; (ii) a second laser that generates a second laser beam having the first polarization state; (iii) a polarization rotator that rotates the polarization of second laser beam to provide a rotated second laser beam having a second polarization state; (iv) a polarization beam combiner that combines the first laser beam and the rotated second laser beam to form a combination beam; and (v) an optical assembly that expands and collimates the combination beam to provide the output beam.

As an overview, with this design, the laser assembly 10 can have relatively high power, while being optically and mechanically stable during temperature cycles and mechanical vibrations. As a result thereof, the laser assembly 10 generates the output beam 12 that is accurately pointed in the far field, and the pointing of the output beam 12 is relatively insensitive to temperature cycles and mechanical vibrations of the laser assembly 10.

In one implementation, one or each laser is a mid-infrared laser that directly generates a laser beam having a center wavelength in a mid-infrared wavelength range. Further, one or each laser can be a tunable mid-infrared laser. As used herein, the mid-infrared wavelength range (“MIR range”) shall include wavelengths of two to twenty microns (2-20 μm).

The combination beam is directed along a combination axis, and the optical assembly is coaxial with the combination axis. Further, the optical assembly can define an on-axis telescope.

In alternative, non-exclusive implementations, the optical assembly can have a beam size magnification of at least 100, 500, or 1000, or an angular magnification of 1/100, 1/500, or 1/000.

In alternative, non-exclusive implementations, the laser assembly can be designed so that the output beam has a power of at least 0.001, 0.01, 0.1, or 1 kilowatt.

The present invention is also directed to a method for generating an output beam.

In yet another implementation, the laser assembly generates a midinfrared output beam and includes (i) a first laser that generates a first laser beam in a midinfrared range having a first polarization state; (ii) a second laser that generates a second laser beam in the midinfrared range having the first polarization state; (iii) a polarization rotator that rotates the polarization of second laser beam to provide a rotated second laser beam having a second polarization state; (iv) a polarization beam combiner that combines the first laser beam and the rotated second laser beam to form a combination beam; and (v) an optical assembly that receives the combination beam and provides the midinfrared output beam.

In still another implementation, the laser assembly comprising: a laser that generates a laser beam; and an optical assembly that receives the laser beam, the optical assembly defining an effective telescope having a beam size magnification of at least one hundred.

Additionally or alternatively, (i) the optical assembly can define an on-axis telescope; (ii) the laser is a mid-infrared laser and the laser beam is at a mid-infrared wavelength; and/or (iii) the telescope has a beam size magnification of at least two hundred.

In another implementation, the laser assembly includes one or more of the following features: (i) a first laser that generates a first laser beam having a first polarization state; (ii) a second laser that generates a second laser beam; (iii) a polarization beam combiner that combines the first laser beam and the rotated second laser beam to form a combination beam; (iv) an optical assembly that expands and collimates the combination beam to provide the output beam; (v) wherein the second laser generates the second laser beam having the first polarization state; and the laser assembly includes a polarization rotator that rotates the polarization of second laser beam to provide a rotated second laser beam having a second polarization state; (vi) wherein the second laser generates the second laser beam having a second polarization state that is different from the first polarization state; (vii) wherein each laser is a mid-infrared laser and each laser beam is at a mid-infrared wavelength; (viii) wherein each mid-infrared laser is a tunable mid-infrared laser; (ix) wherein the combination beam is directed along a combination axis, and wherein the optical assembly is coaxial with the combination axis; (x) wherein the optical assembly defines an on-axis telescope; (xi) wherein the optical assembly has a beam size magnification of at least ten; (xii) wherein the optical assembly has a beam size magnification of at least one hundred; and/or (xiii) wherein the output beam has a power of at least one watt.

In still another implementation, the laser assembly includes one or more of the following features: (i) a first laser that generates a first laser beam in a mid-infrared range having a first polarization state; (ii) a second laser that generates a second laser beam in the mid-infrared range; (iii) a polarization beam combiner that combines the first laser beam and the rotated second laser beam to form a combination beam; (iv) an optical assembly that receives the combination beam and provides the mid-infrared output beam; (v) wherein the second laser generates the second laser beam having the first polarization state; and the laser assembly includes a polarization rotator that rotates the polarization of second laser beam to provide a rotated second laser beam having a second polarization state; (vi) wherein the second laser generates the second laser beam having a second polarization state that is different from the first polarization state; (vii) wherein the optical assembly defines an on-axis telescope; (viii) wherein the optical assembly has a beam size magnification of at least ten; and/or (ix) wherein the optical assembly has a beam size magnification of at least one hundred.

In yet another implementation, the laser assembly includes one or more of the following features: (i) a laser that generates a laser beam; (ii) an optical assembly that receives the laser beam, the optical assembly defining an effective telescope having a beam size magnification of at least one hundred; (iii) wherein the optical assembly defines an on-axis telescope; (iv) wherein the laser is a mid-infrared laser and the laser beam is at a mid-infrared wavelength; and/or (v) wherein the telescope has a beam size magnification of at least two hundred.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1A is simplified top plan illustration of one implementation of a laser assembly;

FIG. 1B is simplified schematic illustration of a portion of the laser assembly of FIG. 1A;

FIG. 2 is simplified schematic illustration of a portion of another laser assembly;

FIG. 3 is a simplified side plan illustration of another implementation of a portion of the laser assembly in partial cutaway secured to a structure;

FIG. 4A is a perspective view of another implementation of the laser assembly;

FIG. 4B is a perspective view of a portion of the laser assembly of FIG. 4A;

FIG. 4C is a perspective view of a portion of the laser assembly of FIG. 4B;

FIG. 4D is an alternative perspective view of the portion of the laser assembly of FIG. 4C;

FIG. 4E is a top plan view of the portion of the laser assembly of FIG. 4C; and

FIG. 5 is simplified top plan illustration of another implementation of a laser assembly.

### DESCRIPTION

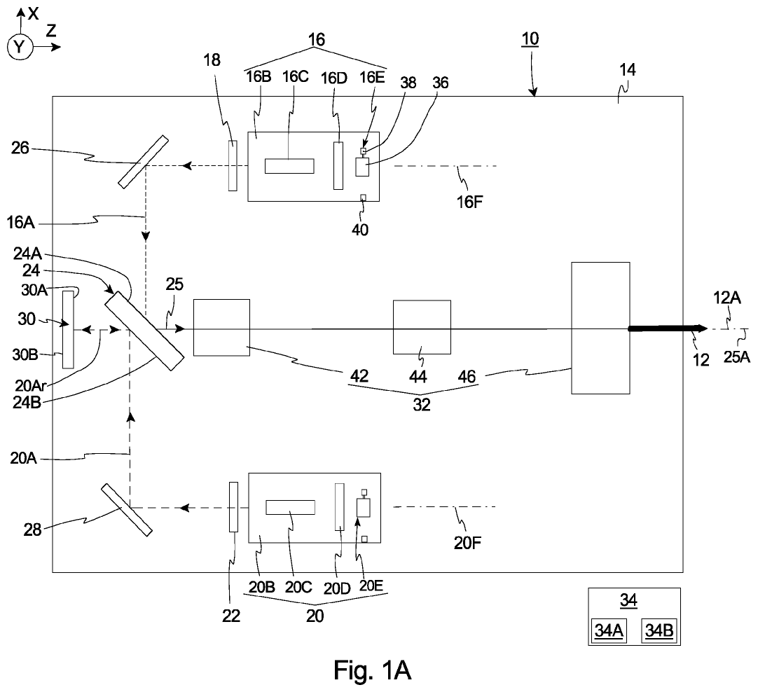

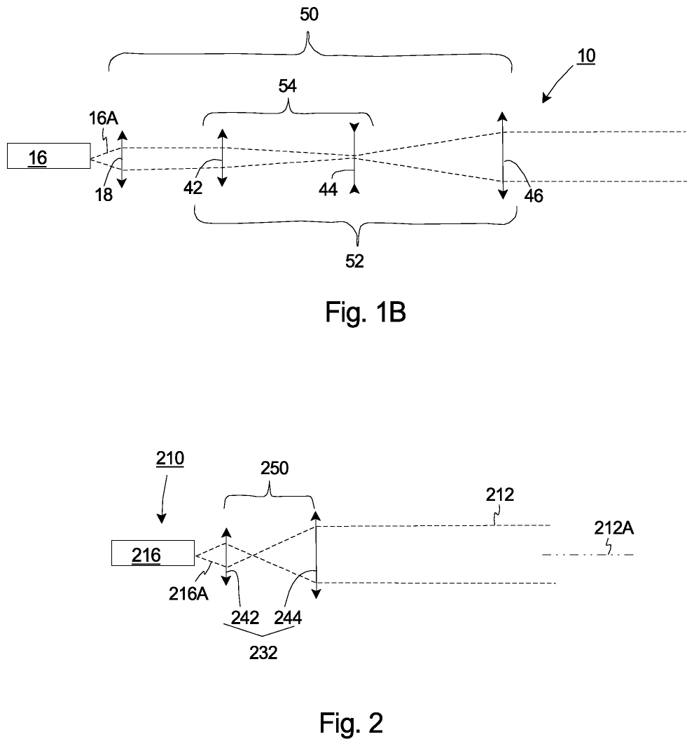

FIG. 1A is simplified top plan illustration of one implementation of a laser assembly 10 that generates an output beam 12 (illustrated with a thick, solid arrow) along an output axis 12A. In this non-exclusive implementation, the laser assembly 10 includes (i) a mounting frame 14, (ii) a first laser 16 that generates a first laser beam 16A (illustrated with short dashed arrow); (iii) a first lens assembly 18 that collimates the first laser beam 16A; (iv) a second laser 20 that generates a second laser beam 20A (illustrated with long dashed arrow); (v) a second lens assembly 22 that collimates the second laser beam 20A; (vi) a beam combiner 24 that combines the laser beams 16A, 20A to provide a combination beam 25 (illustrated with a thin, solid arrow); (vii) a first redirector 26 that directs the first laser beam 16A at the beam combiner 24; (viii) a second redirector 28 that directs the second laser beam 20A at the beam combiner 24; (ix) a polarization rotator 30 that changes the polarization of the second laser beam 20A; (x) an optical assembly 32 that expands and collimates the combination beam 25 to provide the collimated output beam 12; and (xi) a system controller 34 that controls one or more of the components of the laser assembly 10. The design, size, position and/or shape of these components can be varied pursuant to the teachings provided herein. Further, the laser assembly 10 can be designed with more or fewer components than illustrated in FIG. 1A, and/or the arrangement of these components can be different than that illustrated in FIG. 1A.

A number of Figures include an orientation system that illustrates an X axis, a Y axis that is orthogonal to the X axis, and a Z axis that is orthogonal to the X and Y axes. It should be noted that these axes can also be referred to as the first, second, and third axes.

As an overview, the components of the laser assembly 10 are uniquely positioned and designed so that the laser assembly 10 is relatively high power, and is optically and mechanically stable during temperature cycles and mechanical vibrations. As a result thereof, the laser assembly 10 generates the output beam 12 that is accurately pointed in the far field, and the pointing of the output beam 12 is relatively insensitive to temperature cycles and mechanical vibrations of the laser assembly 10. Thus, the laser assembly 10 will be on target in the far field. As used herein, the term “near field” shall mean the region around the output aperture of the optical assembly 32, and the term “far field” shall mean the region located many Rayleigh ranges away from the optical assembly 32.

As non-exclusive examples, the laser assembly 10 can be designed so that the power output of the output beam 12 is at least 0.001, 0.01, 0.1 or 1 Kilowatt. The high powered, laser assembly 10 disclosed herein can be used in a number of different applications. As non-exclusive examples, the laser assembly 10 can be used for test labs, industrial cutting, welding, general illumination, material processing, gas leak detection, fiber optic testing, epoxy curing, or spectroscopy.

In certain implementations, the laser assembly 10 can generate an output beam 12 having a beam quality of that is perfect (1.00). Alternatively, the laser assembly 10 can generate an output beam 12 that is a near perfect (e.g. at least 1.05) or near diffraction limited.

In certain implementations, the laser assembly 10 can have a relatively small form factor. In one, non-exclusive example, the laser assembly 10 can have a form factor of less than 25 millimeter by 45 millimeters by 55 millimeters. As alternative, non-exclusive examples, the laser assembly 10 can have a form factor of less than 50, 60, 70 or 80 meters cubed.

The mounting frame 14 provides a rigid platform for supporting (i) the lasers 16, 20; (ii) the lens assemblies 18, 22; (iii) the beam combiner 24; (iv) the redirectors 26, 28; (v) the polarization rotator 30; and (vi) the optical assembly 32; and maintains these components in precise mechanical alignment. Additionally, the mounting frame 14 can include a temperature controller (not shown in FIG. 1A) for controlling the temperature of the mounting base 14. Moreover, the mounting frame 14 can be designed to provide a controlled environment for some or all of the components. Non-exclusive examples of suitable materials for the mounting frame 14 include magnesium, aluminum, carbon fiber composite, molybdenum copper alloy, copper tungsten, AlSiC, nickel-cobalt ferrous alloys, and silver-diamond.

The first laser 16 directly generates the first laser beam 16A. Similarly, the second laser 20 directly generates the second laser beam 20A. The design of each laser 16, 20 can be varied pursuant to the teachings provided herein. In one, non-exclusive implementation, each laser 16, 20 can be selectively tunable over a predetermined wavelength range to selectively tune the wavenumber of each laser beam 16A, 20A, and the output beam 12. In one, non-exclusive example, each laser 16, 20 can be selectively tuned over a portion or the entire MIR range. In this example, each beam 16A, 20A has a center wavelength in the MIR range. Moreover, each laser 16, 20 can be designed so that the power output of the respective laser beam 16A, 20A is at least 0.001, 0.01, 0.1, or 1 Kilowatts.

It should be noted that the lasers 16, 20 can be similar or different in design. In the embodiment illustrated in FIG. 1A, each laser 16, 20 is similar in design. In one embodiment, each laser 16, 20 is an extended cavity, tunable, mid infrared laser. Alternatively, one or both lasers 16, 20 can be fabry perot laser. Still alternatively, one or both lasers 16, 20 can be tuned and subsequently fixed at a desired wavelength.

In the implementation of FIG. 1A, (i) the first laser 16 includes a first laser frame 16B, a first gain medium 16C, a first cavity optical assembly 16D, and a first wavelength selective (“WS”) feedback assembly 16E; and (ii) the second laser 20 includes a second laser frame 20B, a second gain medium 20C, a second cavity optical assembly 20D, and a second wavelength selective (“WS”) feedback assembly 20E. The design of each of these components can be varied.

The first laser frame 16B provides a rigid support for the components of the first laser 16; and the second laser frame 20B provides a rigid support for the components of the second laser 20. In certain embodiments, each laser frame 16B, 20B is made of a rigid material having (i) a high modulus of elasticity (e.g. at least 250 Gpa); (ii) a high stiffness (e.g. at least 25,000,000 [Pa/(kg/m\hat{ }3)]; (iii), low thermal expansion (e.g. coefficient of thermal expansion of less than seven parts per million/degrees Celsius), a relatively high thermal conductivity (e.g. thermal conductivity of greater than 100 watts/meter-Kelvin) to readily transfer heat away from the respective gain medium 16C, 20C.

Each gain medium 16C, 20C can directly emit the respective beams 16A, 20A without any frequency conversion in the mid infrared range. As non-exclusive examples, each gain medium 16C, 20C can be a Quantum Cascade (QC) gain medium, an Interband Cascade (IC) gain medium, or a mid-infrared diode. In another example, each gain medium can be a laser diode that directly generates in the 375 nanometer to two micron range. As provided herein, the fabrication of each gain medium 16C, 20C can be altered to achieve the desired output frequency range. As a non-exclusive example, the thickness of the wells/barriers of a Quantum Cascade gain medium determine the wavelength characteristic of the respective Quantum Cascade gain medium. Thus, fabricating a Quantum Cascade gain medium of different thickness enables production of the laser having different output frequencies within the MIR range.

In this embodiment, each gain medium 16C, 20C includes (i) a first facet that faces the respective cavity optical assembly 16D, 20D and the respective wavelength selective element 16E, 20E, and (ii) a second facet that faces the respective lens assembly 18, 22; and each gain medium 16C, 20C emits from both facets. In one embodiment, each first facet is coated with an anti-reflection (“AR”) coating, and each second facet is coated with a partly reflective coating. With this design, for each laser 16, 20, the reflective second facet of the gain medium 16C, 20C acts as a first end (output coupler) of an external cavity, and the wavelength selective element 16E, 20E defines a second end of each external cavity.

The first cavity optical assembly 16D is positioned between the first gain medium 16C and the first feedback assembly 16E along a first lasing axis 16F of the first laser 16. The first cavity optical assembly 16D collimates and focuses the beam that passes between these components. Similarly, the second cavity optical assembly 20D is positioned between the second gain medium 20C and the second feedback assembly 20E along a second lasing axis 20F of the second laser 20. The second cavity optical assembly 20D collimates and focuses the beam that passes between these components. In the non-exclusive implementation of FIG. 1A, the first lasing axis 16F and the second lasing axis 20F each are parallel to the Z axis and are spaced apart.

For example, each cavity optical assembly 16D, 20D can include one or more lens. Further, the lens can be an aspherical lens having an optical axis that is aligned with the respective lasing axis 16F, 20F. In alternative, non-exclusive embodiments, each lens can have a diameter of less than approximately one, two, three, four, five or ten millimeters. The type of material utilized for each lens can be selected to work with the wavelength of the laser beams 16A, 20A. For example, for a mid-infrared laser beam 16A, 20A, non-exclusive examples of suitable materials for the lens include germanium and zinc selenide. In a non-exclusive embodiment, a Numerical Aperture of each lens is chosen to approximately match a Numerical Aperture of its respective laser beam 16A, 20A. This results in the most compact system, and has the further advantage of maximizing the beam size relative to the lens diameter.

The first wavelength selective element 16E reflects the beam back to the first gain medium 16C, and is used to precisely select and adjust the lasing frequency of the first laser 16. Similarly, the second wavelength selective element 20E reflects the beam back to the second gain medium 20C, and is used to precisely select and adjust the lasing frequency of the second laser 20. In this manner, the respective beams 16A, 20A may be tuned with the wavelength selective element 16E, 20E without adjusting the respective gain medium 16C, 20C. Thus, with the external cavity arrangements disclosed herein, the wavelength selective element 16E, 20E dictates what wavelength will experience the most gain in each laser 16, 20.

A number of alternative embodiments of the wavelength selective element 16C, 20C can be utilized. In FIG. 1A, each wavelength selective element 16E, 20E includes a grating 36, a grating mover 38 (e.g. a voice coil actuator), and a feedback detector 40. The grating mover 38 selectively moves (e.g. rotates about the X axis in this example) the grating 36 to rapidly adjust the lasing frequency of the respective gain medium 16C, 20C. Further, the rotational position and/or movement of the grating 36 can be continuously monitored with the feedback detector 40 that provides for closed loop control of the grating mover 38. As non-exclusive examples, for each laser 16, 20, the grating mover 38 moves the grating 36 to adjust the angle of incidence θ over the entire adjustment range to scan the wavelength range in less than approximately 0.001, 0.01, 0.1, 0.5, 1, 2, 3, 4, 5, 6, 7, 8, 9, 10, 12, 14, 16, 18, 20, or more seconds.

The feedback detector 40 generates a grating feedback signal that relates to the position of the respective grating 36 and/or the angle of incidence θ of the beam on the respective grating 36. As a non-exclusive example, the feedback detector 40 can be an optical encoder that includes a plurality of encoder marks, and an optical reader. With this design, the wavelength of each beam 16A, 20A can be selectively tuned in a closed loop fashion.

Alternatively, for example, the wavelength selective element 16E, 20E can be another type of frequency selective element. A discussion of the techniques for realizing the full laser tuning range from a semiconductor device can be found in M. J. Weida, D. Caffey, J. A. Rowlette, D. F. Arnone and T. Day, “Utilizing broad gain bandwidth in quantum cascade devices”, Optical Engineering 49 (11), 111120-111121-111120-111125 (2010). As far as permitted, the contents of this article are incorporated herein by reference.

In one implementation, the first laser 16 emits the first laser beam 16A having a first polarization state, and the second laser 20 emits the second laser beam 20A also having the first polarization state. For example, for a QC gain medium 16C, 20C, each laser 16, 20 can be designed so that each light beam 16A, 20A is linearly polarized with the electric field polarization oriented along the Y axis of FIG. 1A. In this example, each of the QC gain mediums 16C, 20C is mounted epi-side down. It should be noted that the QC gain mediums 16C, 20C can be mounted in a different orientation to change the orientation of the electric field polarization. For example, one or both of the QC gain mediums 16C, 20C can be mounted in a fashion so that the electric field polarization is oriented along the X axis. In a non-exclusive implementation, the laser assembly 10 can be built with the first QC gain medium 16C generating the laser beam 16A having an electric field polarization oriented along the Y axis, the second QC gain medium 20C generating the laser beam 20A having an electric field polarization oriented along the X axis, and without the polarization rotator 30. In this arrangement, for example, the second laser 20 can be positioned where the polarization rotator 30 is located in FIG. 1A.

The first lens assembly 18 is positioned near the second facet of the first gain medium 16C along the first lasing axis 16F, and collimates the first laser beam 16A that exits the second facet of the first gain medium 16C. Similarly, the second lens assembly 22 is positioned near the second facet of the second gain medium 20C along the second lasing axis 20F, and collimates the second laser beam 20A that exits the second facet of the second gain medium 20C. For example, each lens assembly 18, 22 can include one or more lens elements. For example, each lens assembly 18, 22 can be an aspherical lens having an optical axis that is aligned with the respective lasing axis 16F, 20F. In alternative, non-exclusive embodiments, each lens can have a diameter of less than approximately one, two, three, four, five or ten millimeters. The type of material utilized for each lens can be selected to work with the wavelength of the laser beams 16A, 20A. For example, for a mid-infrared laser beam 16A, 20A, non-exclusive examples of suitable materials for the lens include Germanium and zinc selenide. In a non-exclusive embodiment, a Numerical Aperture of each lens is chosen to approximately match a Numerical Aperture of its respective laser beam 16A, 20A. This results in the most compact system, and has the further advantage of maximizing the beam size relative to the lens diameter.

As a specific non-exclusive example, each lens assembly 18, 22 can be asphere, have a focal length of 0.5 millimeters and be made of Germanium. However, other materials that work with the wavelengths of the laser beams 16A, 20A can be utilized. Alternatively, a reflective lens could be used.

The beam combiner 24 combines the first laser beam 16A and second laser beam 20A to provide the combination beam 25 that is directed along a combination axis 25A. In the non-exclusive implementation of FIG. 1A, the combination axis 25A is parallel to the Z axis, the first lasing axis 16F, and the second lasing axis 20F; and the combination axis 25A is spaced apart from and positioned between the lasing axes 16F, 20F.

In one, non-exclusive implementation, the beam combiner 24 is a polarization beam combiner that reflects light at a first polarization state and transmits light at a second polarization state. For example, the beam combiner 24 can reflect light having the electric field polarization oriented along the Y axis, and transmit light having the electric field polarization oriented along the X axis. In FIG. 1A, the beam combiner 24 is at an approximately forty-five (45) degree angle relative to the Z axis, and includes (i) a first combiner side 24A that faces the optical assembly 32 and the first director 26; and (ii) an opposed second combiner side 24B that faces the polarization rotator 30 and the second director 28. In this design, the first combiner side 24A includes an anti-reflective coating, and the second combiner sider 24B includes a polarization beam combining coating. With this design, the first laser beam 16A is refracted by the first combiner side 24A and reflected by the second combiner side 24B; and the second laser beam 20A is reflected ninety degrees with the second combiner side 24B at the polarization rotator 30. Subsequently, the second laser beam 20A is directed by the polarization rotator 30 back at the beam combiner 24 and the second laser beam 20A combines with the first laser beam 16A at the second combiner side 24B.

The first redirector 26 directs the first laser beam 16A at the beam combiner 24, and the second redirector 28 directs the second laser beam 20A at the beam combiner 24. The design of each redirector 26, 28 can be varied to suit the layout of the laser assembly 10. In one implementation, each redirector 26, 28 is a reflective turn mirror. In this design, the first laser beam 16A that is initially directed along the first lasing axis 16F (parallel to the Z axis), is redirected by the first redirector 26 (ninety degrees) along the X axis at the beam combiner 24. Similarly, the second laser beam 20A that is initially directed along the second lasing axis 20F (parallel to the Z axis) is redirected by the second redirector 28 (ninety degrees) along the X axis at the beam combiner 24.

The polarization rotator 30 changes the polarization of the second laser beam 20A. In one embodiment, the polarization rotator 30 includes a first rotator side 30A that is transmissive to the second laser beam 20A, and an opposed second rotator side 30B that includes a highly reflective coating to the second laser beam 20A. For example, the polarization rotator 30 can be made of Sapphire or another type of material that rotates the polarization of the second laser beam 20A. In this non-exclusive example, the polarization rotator 30 is a one-quarter waveplate that changes the polarization of the second laser beam 20A one-quarter wavelength for each pass (¼+¼=½ wave rotation and ninety degrees polarization rotation). Since the second laser beam 20A makes two passes in the polarization rotator 30, the polarization of the second laser beam 20A at the first polarization state is rotated to a second laser beam 20Ar having the second polarization state exiting the polarization rotator 30. Stated in another fashion, since the second laser beam 20A makes two passes in the polarization rotator 30, the electric field polarization is rotated from being oriented along the Y axis to being oriented along the X axis. Further, the rotated second laser beam 20Ar is directed back at the beam combiner 24. Because the rotated second laser beam 20Ar is now at the second polarization state, it is transmitted through the beam combiner 24 and combined with the first laser beam 16A along the combination axis 25A.

With this design, the second laser beam 20A reflected from the beam combiner 24 (because it is at the first polarization state) is directed at the first rotator side 30A where it is transmitted into the polarization rotator 30 and reflected by the second rotator side 30B back towards the beam combiner 24. The two passes through the polarization rotator 30 rotates the polarization of the second laser beam 20A to the second polarization state. At this time, the second laser beam 20A is transmitted through the beam combiner 24.

In certain implementations, the optical assembly 32 expands and collimates the combination beam 25 to provide the output beam 12. The design of the optical assembly 32 can be varied pursuant to the teachings provided herein. In the non-exclusive implementation of FIG. 1A, the optical assembly 32 includes a first lens 42, a second lens 44, and a third lens 46 that are spaced apart along the combination axis 25A and the output axis 12A. In this design, the first lens 42 that is closest the beam combiner 24, the second lens 44 is the next closest the beam combiner 24, and a third lens 42 is farthest from the beam combiner 24. In the implementation of FIG. 1A, (i) the first lens 42 is an on-axis focusing lens, (ii) the first lens 42 and the second lens 44 cooperate to define an on-axis refractive telescope; and (iii) the third lens 46 is an on-axis projection lens.

In one non-exclusive example, (i) the first lens 42 can be a disk shaped, convex element that focuses the combination beam 25 from the beam combiner 24 on the second lens 44; (ii) the second lens 44 can be a disk shaped, diverging element that diverges the combination beam 25, and (iii) the third lens 46 can be a disk shaped, collimating element that collimates the combination beam 25 to launch the output beam 12 into free space. In one implementation, the lenses 42, 44, 46 are spaced apart from each other, and centered and coaxial with the output axis 12A.

As a specific, non-exclusive example, (i) the first lens 42 is spherical, has a focal length of 9.2 millimeters and is made of Zinc Selenide; (ii) the second lens 44 is asphere, has a focal length of 0.345 millimeters and is made of Germanium; and (iii) the third lens 42 is asphere, has a focal length of 8.9 millimeters and is made of Zinc selenide.

Together, the first and second lenses 42, 44 form a beam expander that expands the combination beam 25, and the third lens 46 is a projection lens that collimates the expanded beam 25.

In FIG. 1A, the first lens assembly 18 is coaxial with the first lasing axis 16F, the second lens assembly 22 is coaxial with the second lasing axis 20F, and the lenses 42, 44, and 46 are coaxial with and spaced apart along the output axis 12A.

FIG. 1B is a simplified illustration of the first laser 16 (including a QC gain medium) launching the first laser beam 16A, and how the first laser beam 16A travels through the first lens assembly 18, the first lens 42, the second lens 44, and third lens 46. It should be noted that the second laser beam 20A (not shown in FIG. 1B) from the second laser 20 (not shown in FIG. 1B) can have a similar path design.

In the non-exclusive implementation of FIG. 1B, (i) the first lens assembly 18 can be a collimating lens having a focal length of 0.5 millimeters (f=0.5 mm); (ii) the first lens 42 can be a spherical lens made of Zinc selenide, and having a focal length of 9.2 millimeters (f=9.2 mm); (iii) the second lens 44 can be an asphere lens made of Germanium, and having a focal length of 0.345 millimeters (f=0.345 mm); and (ii) the third lens 46 can be an asphere lens made of Zinc selenide, and having a focal length of 8.9 millimeters (f=8.9 mm). However, other designs are possible.

In the non-exclusive implementation of FIG. 1B, (i) the first lens assembly 18, the first lens 42, the second lens 44, and the third lens 46 cooperate to form an overall effective telescope 50 having a beam size magnification of 477 (m=477) (or a beam divergence decrease of 1/477); (ii) the first lens 42, the second lens 44, and the third lens 46 cooperate to form an effective lens assembly 52 having an effective focal length of 239 (EFL=239); and (iii) the first lens 42 and the second lens 44 cooperate to form a telescope portion 54 having a beam size magnification of 1/27 (the beam is 27 times smaller, but also 27 times more divergent). With this design, the size of the first laser beam 16A exiting the gain medium 16C is magnified 477 times. Further, the output beam 12 exiting the laser assembly 10 will have very low divergence (e.g., single digit milliradians). However, other designs are possible. The second laser can have a similar beam path characteristics.

As alternative, non-exclusive implementations, (i) the first lens assembly 18, the first lens 42, the second lens 44, and the third lens 46 cooperate to form an effective telescope 50 having a beam size magnification of at least 10, 100, 200, 250, 500, or 1000; (ii) the first lens 42, the second lens 44, and the third lens 46 cooperate to form an effective lens 52 having an effective focal length of at least 10, 100, 250, 500, or 1000; and/or (iii) the first lens 42 and the second lens 44 can combine 254 to have a beam size magnification of at least 10, 50, 100, 250, or 500.

With this design, the three common axis lenses 42, 44, 46 cooperate to minimize pointing errors of the output beam 12 due to (i) movement of lenses 42, 44, 46, the lasers 16, 20, and the lens assemblies 18, 22, and (ii) rotation of the beam directors 26, 28, the beam combiner 24, and the polarization rotator 30. Stated in another fashion, the telescope design minimizes absolute beam pointing errors (provides absolute beam pointing stability) the far field, and the laser assembly 10 is relatively insensitive to optical movements.

It should be noted that the first lens assembly 18 collimates the laser light 16A after it exits the first laser 16. The longer the focal length of the first lens assembly 18, the larger the beam diameter, the lower the divergence, and the larger the size.

Referring back to FIG. 1A, the system controller 34 controls one or more of the components of the laser assembly 10. For example, the system controller 34 can direct current to each gain medium 16C, 20C, and control each feedback assembly 16E, 20E. The system controller 34 can include one or more processors 34A, one or more electronic storage devices 34B, one or more circuit boards, and/or one or more connectors. The system controller 34 is illustrated in FIG. 1A as a centralized system. Alternatively, the system controller 34 can be a distributed system.

The laser assembly 10 can be powered by a generator, a battery, or another power source.

It should be noted that the design and arrangement of the components of the laser assembly 10 allow for the laser assembly 10 to have a relatively high output power and high radiance because the output of multiple lasers 16, 20 are combined, while being optically and mechanically stable during temperature cycles and mechanical vibrations. As a result thereof, the laser assembly 10 generates the output beam 12 that is accurately pointed in the far field, and the pointing of the output beam 12 is relatively insensitive to temperature cycles and mechanical vibrations of the laser assembly 10.

More specifically, with the unique design arrangement illustrated in FIG. 1A, movement of the following components (e.g. due to temperature changes and/or mechanical vibrations) will result in the corresponding pointing error in the output beam 12 in the far field: (i) movement of the laser facet of the first laser 16 will result in a pointing error of

$$\frac{\partial ∝}{\partial x} = - 30 μ Rad / μm ;$$

(ii) movement of the first lens assembly 18 will result in a pointing error of

$$\frac{\partial ∝}{\partial x} = 26 μ Rad / μm ;$$

(iii) movement of the first redirector 26 will result in a pointing error of

$$\frac{\partial ∝}{\partial θ} = ∼ 60 μ Rad / mRad ;$$

(iv) movement of the beam combiner 24 for the first beam will result in a pointing error of

$$\frac{\partial ∝}{\partial θ} = ∼ 132 μ Rad / mRad ;$$

(v) movement of the beam combiner 24 for the second beam will result in a pointing error of

$$\frac{\partial ∝}{\partial θ} = ∼ 77 μ Rad / mRad ;$$

(vi) movement of the polarization rotator 30 will result in a pointing error of

$$\frac{\partial ∝}{\partial θ} = ∼ 104 μ Rad / mRad ;$$

(vii) movement of the laser facet of the second lens assembly 22 in a pointing error of

$$\frac{\partial ∝}{\partial x} = 32 μ Rad / μm ;$$

(viii) movement of the second lens assembly 22 will result in a pointing error of

$$\frac{\partial ∝}{\partial x} = - 36 μ Rad / μm ;$$

(ix) movement of the second redirector 28 will result in a pointing error of

$$\frac{\partial ∝}{\partial θ} = ∼ 60 μ Rad / mRad ;$$

(x) movement of the first lens 42 will result in a pointing error of

$$\frac{\partial ∝}{\partial x} = 8 μ Rad / μm ;$$

(xi) movement of the second lens 44 will result in a pointing error of

$$\frac{\partial ∝}{\partial x} = - 116 μ Rad / μm ;$$

and (xii) (x) movement of the third lens 46 will result in a pointing error of

$$\frac{\partial ∝}{\partial x} = 112 μ Rad / μm .$$

Importantly, all of these values are relatively low with the most sensitive element being the projection lens 46. This results in the laser assembly 10 being optically and mechanically stable during temperature cycles and mechanical vibrations. In certain implementations, the third lens 46 (projection lens) is designed to have the largest focal length while still having the desired divergence. This reduces the movement sensitivity of the projection lens 46. As alternative, non-exclusive implementations, the projection lens 46 has a focal length of at least 5, 10, 15, 20, 25, 30, 40, 50, or 100 millimeters. As a result of the long focal length, the movement of the projection lens 46 results in very little point error of the output beam 12 in the far field.

With the designs of the optical assembly 32 disclosed herein, the front focal plane of the projection lens 46 is at the effective back focal plane of the first lens assembly 16 and the lenses 42, 44. As a result thereof, movement of the lasers 16, 20 and the other components will result in merely a slight positional shift in the position of the output beam 12 relative to the output axis 12A, without changing the angle of the output beam 12. Thus, the output beam 12 will remain substantially parallel to the output axis 12A, and the positional shift will only result in a slight pointing error in the far field. The present design is angularly insensitive and positionally sensitive. Further, the larger the beam diameter of the output beam 12, the smaller the divergence of the output beam 12.

In summary, with the present design, possible movements of the various components of the laser assembly 10 will result in relatively very slight pointing errors in the far field. As a result the laser assembly 10 is relatively insensitive to temperature cycles and mechanical vibrations. Stated in another fashion, the design of laser assembly 10 (with the telescope optical assembly plus projection lens) desensitizes the output beam 12 to pointing errors caused by (i) positional shifts in the lasers 16, 20, the lens assemblies 18, 22; and (ii) angular shifts in the redirectors 26, 28, the beam combiner 24, and the polarization rotator 30.

FIG. 2 is a simplified illustration of another implementation of the laser assembly 210. In this simplified illustration, the laser assembly 210 includes a quantum cascade laser 216 having a high numerical aperture that generates and launches a diverging laser beam 216A in the mid-infrared range, and an optical assembly 232 that expands and effectively collimates the laser beam 216A to generate the output beam 212 along the output axis 212A. Alternatively, the laser 216 can be another type of laser, such as a semiconductor diode. It should be noted that other components of the laser assembly 210 (e.g. the mounting frame and the system controller) are not shown for simplicity.

The laser 216 can be similar to the corresponding lasers 16, 20 described above and illustrated in FIG. 1A. However, in FIG. 2, the laser beam 216A is not immediately collimated because this embodiment does not include the first lens assembly 18 (illustrated in FIG. 1B). Instead, the diverging laser beam 216A is directed into the optical assembly 232 which is effectively a high magnification telescope. With this design, the output beam 212A exiting the optical assembly 232 has low divergence and approaches being collimated. Thus, in this design, an initial collimation lens is not necessary, and the telescope practically collimates the output beam 212 so that the output beam 212 has low divergence. The laser facet far field is projected. When the laser facet is collimated by a single lens, the laser facet near field is projected.

In the non-exclusive implementation of FIG. 2, the optical assembly 232 includes a first lens 242 and a second lens 244 that are spaced apart along the output axis 212A and that are coaxial with the output axis 212A and the laser beam 216. In this design, the second lens 244 functions as a projection lens that projects a far field of the emitter of the laser 216. For example, the first lens 242 can be a spherical lens made of Zinc selenide, and having a focal length of 0.1 millimeters; and the second lens 244 can be an asphere lens made of Zinc selenide, and having a focal length of twenty millimeters. However, other designs are possible.

In FIG. 2, the first lens 242 and second lens 242 cooperate to form an effective telescope 250 having a beam size magnification of two hundred (m=200) (or a beam divergence decrease of 1/200). However, other designs are possible. As alternative, non-exclusive implementations, the first lens 242 and the second lens 244 cooperate to form the telescope 250 having a beam size magnification of at least 10, 100, 200, 300, 400, 500, or 1000.

With this design, the optical assembly 232 is far field pointing insensitive to positional movement of the laser 216 and positional movement of the first lens 242. Further, in this design, the second lens 244 (projection lens) is designed to have a relatively long focal length. As alternative, non-exclusive implementations, the projection lens 244 has a focal length of at least 5, 10, 15, 20, 25, 30, 40, 50, or 100 millimeters. As a result of the long focal length, the movement of the projection lens 244 results in very little pointing error of the output beam 212 in the far field.

Further, with this design, the lenses 242, 244 cooperate to minimize pointing errors of the output beam 212 due to movement of the lens. Stated in another fashion, the telescope design minimizes absolute beam pointing errors (provides absolute beam pointing stability) the far field, and the laser assembly 210 is relatively insensitive to optical movements.

Comparing FIGS. 2 and 1B, the four lenses 18, 42, 44, 46 of FIG. 1B have effectively been replaced with two lenses 242, 244 to simplify the design.

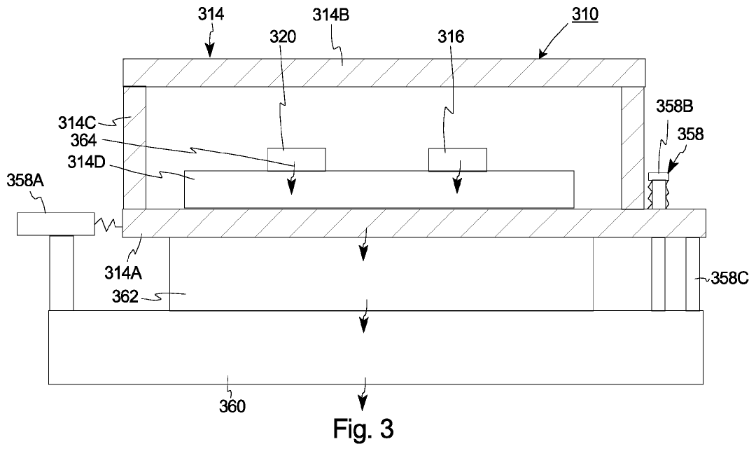

FIG. 3 is a simplified side illustration (in partial cutaway) of another implementation of the laser assembly 310 illustrating a possible, non-exclusive example of the mounting and temperature control for the laser assembly 310. In this non-exclusive implementation, an attachment assembly 358 attaches the laser assembly 310 to a rigid structure 360 (e.g. a heatsink) with a temperature control unit 362 (e.g. a thermoelectric cooler) therebetween. However, the laser assembly 310 can be retained in a fashion different than illustrated in FIG. 3.

It should be noted that many of the components of the laser assembly 310 are not illustrated in FIG. 3. More specifically, in FIG. 3, only the mounting frame 314, the first laser 316, and the second laser 320 are illustrated. In this implementation, the mounting frame 314 forms an enclosed housing (chamber) around the other components of the laser assembly 310. More specifically, the mounting frame 314 can be generally rectangular shaped and include a rigid package base 314A, a rigid lid 314B, and four rigid sides 314C (only three are visible) that maintain the lid 314B spaced apart from the package base 314A. In certain embodiments, the enclosed chamber can be sealed to provide a controlled environment for the sensitive components of the laser assembly 310. For example, the chamber can be filled with an inert gas, or another type of fluid, or subjected to vacuum.

Additionally, the mounting frame 314 can include a laser mount 314D that secures the lasers 316, 318 to the package base 314A. The laser mount 314D can be made of a material having a high heat transfer rate to readily remove heat from the lasers 316, 318. Moreover, the mounting frame 314 can include a window (not shown in FIG. 3) that allows the output beam (not shown in FIG. 3) to exit the mounting frame 314.

With this design, heat 364 (represented with arrows) is primarily transferred from the laser 316 to the laser mount 314D. Next, the heat 364 is transferred from the laser mount 314D to the temperature control unit 362 via the package base 314A. Subsequently, the heat 364 is transferred from the temperature control unit 362 to the structure 360. It should be noted that the laser mount 314D and a portion or all of the mounting frame 314 (e.g. the package base 314A) can be a monolithic structure.

The design of the attachment assembly 358 for securing the laser assembly 310 to the structure 360 can be varied. For example, the attachment assembly 358 can include (i) one or more flexures 358A, (ii) one or more fasteners 358B (e.g. shoulder bolts with spring loading); and/or (iii) one or more alignment pins 358C. However, other attachment assemblies 358 can be utilized.

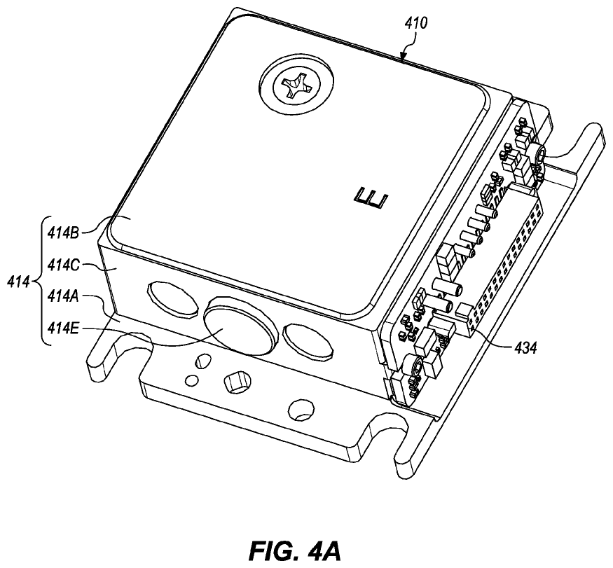

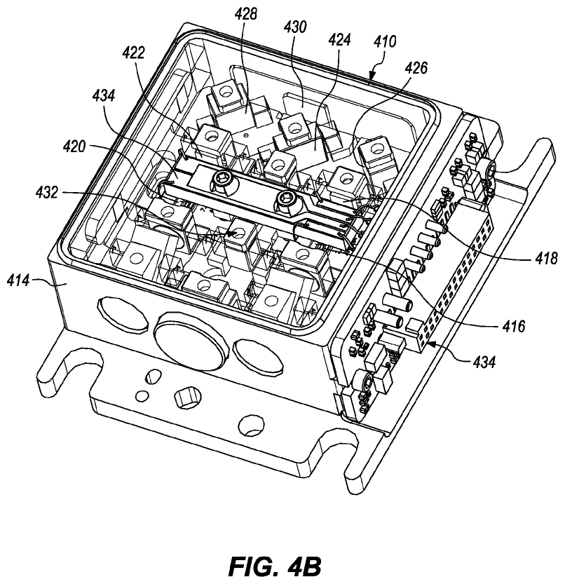

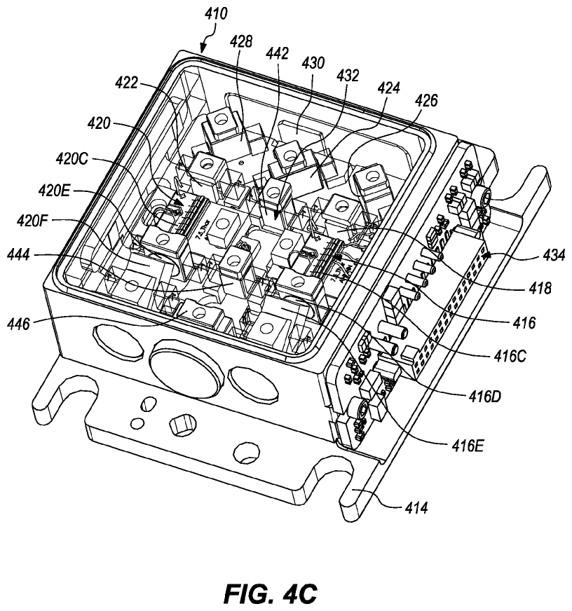

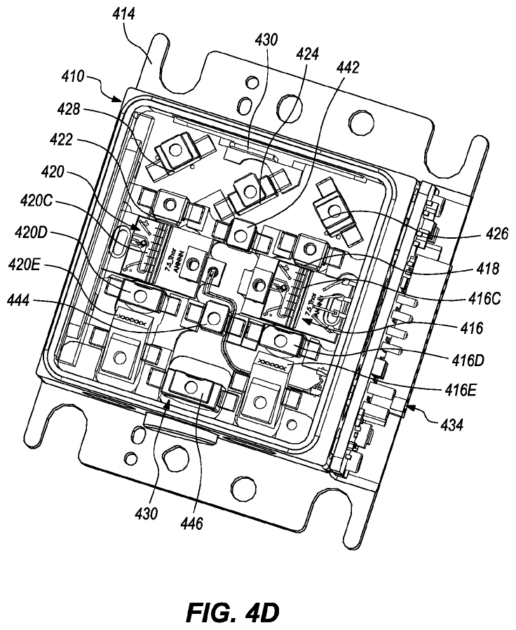

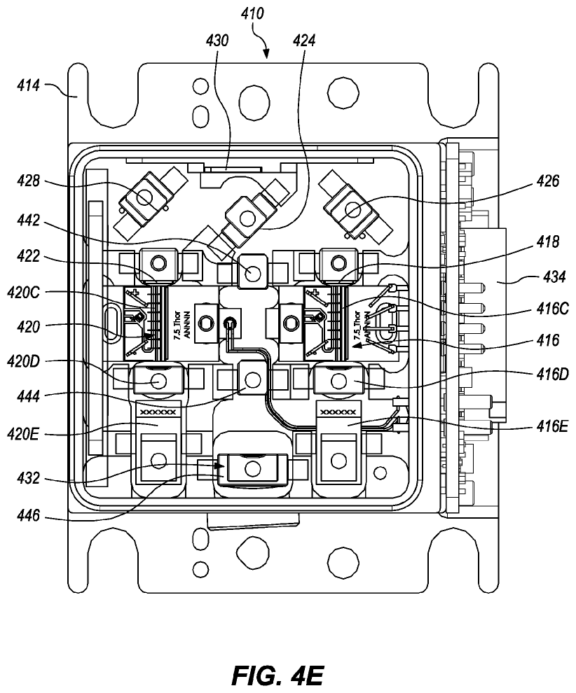

FIG. 4A is a perspective view of another implementation of the laser assembly 410. In FIG. 4A, the mounting frame 414 and a portion of the system controller 434 are visible. In this implementation, the mounting frame 414 again includes a rigid package base 414A, a rigid lid 414B, and four rigid sides 414C (only two are visible in FIG. 4A) that cooperate to form an enclosed chamber. These components are similar to the corresponding components described above. Additionally, FIG. 4A illustrates that the mounting frame 414 can include a window 414E that allows the output beam (not shown in FIG. 4A) to exit the mounting frame 414.

FIG. 4B is a perspective view of a portion of the laser assembly 410 of FIG. 4A. In FIG. 4B, the lid 414B (illustrated in FIG. 4A) of the mounting frame 414 has been removed so that the following components are viewable: (i) the first laser 416; (ii) the first lens assembly 418; (iii) the second laser 420; (iv) the second lens assembly 422; (v) the beam combiner 424; (vi) the first redirector 426; (vii) the second redirector 428; (viii) the polarization rotator 430; (ix) the optical assembly 432; and (x) a portion of the system controller 434. It should be noted that these components can be similar to the corresponding components described above and illustrated in FIG. 1A.

It should be noted that in FIG. 4B, the system controller 434 includes an electrical connector 434C that electrically connects the system controller 434 to the lasers 416, 420.

FIGS. 4C and 4D are alternative perspective views and FIG. 4E is a top view of the laser assembly 410 of FIG. 4A without the lid 414B (illustrated in FIG. 4A) of the mounting frame 414, and without the electrically connector 434C (illustrated in FIG. 4B). At this time, (i) the first laser 416 including the first gain medium 416C, the first cavity optical assembly 416D, and the first wavelength selective feedback assembly 416E; (ii) the first lens assembly 418; (iii) the second laser 420 including the second gain medium 420C, the second cavity optical assembly 420D, and the second wavelength selective feedback assembly 420E; (iv) the second lens assembly 422; (v) the beam combiner 424; (vi) the first redirector 426; (vii) the second redirector 428; (viii) the polarization rotator 430; (ix) the optical assembly 432 including the first lens 442, the second lens 444, and the third lens 446; and (x) a portion of the system controller 434 are visible.

In one implementation, the components of the laser assembly 410 have a low coefficient of thermal expansion (“CTE”), and the coefficient of thermal expansion is matched to further minimize pointing errors due to temperature changes. In alternative, non-exclusive examples, each of components of the laser assembly 410 are designed to have a coefficient of thermal expansion of less than three, four, five, six, seven, or eight parts per million/degrees Celsius. Additionally or alternatively, in non-exclusive examples, the components of the laser assembly 410 are designed to have a coefficient of thermal expansion of within two, three, four or five parts per million/degrees Celsius of each other. Stated alternatively, each component of the laser assembly 410 are designed to have a coefficient of thermal expansion that is within 2, 3, 4, 5, 6, 7, 8, 9, or 10 percent of the coefficient of thermal expansion of any other component in the laser assembly 410.

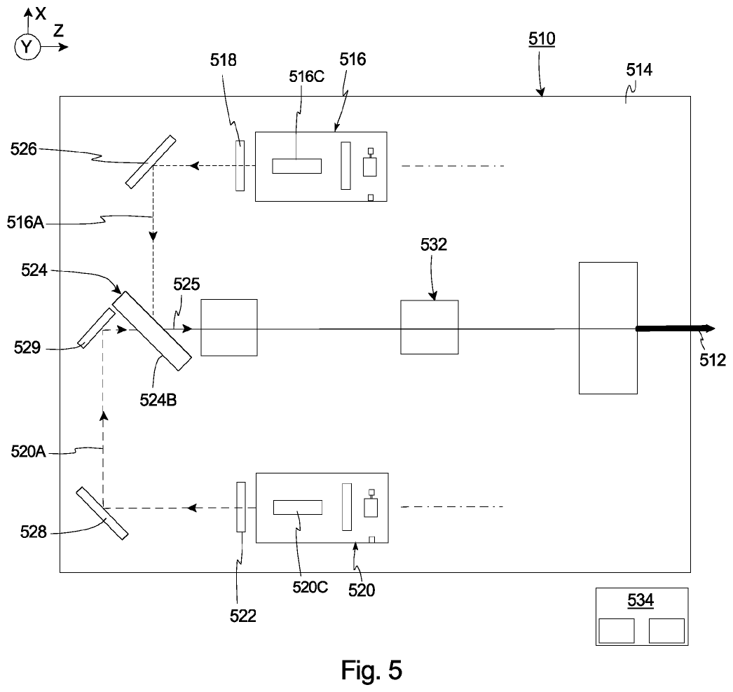

FIG. 5 is simplified top plan illustration of another implementation of a laser assembly 510 that generates an output beam 512. In this non-exclusive implementation, the laser assembly 510 includes (i) a mounting frame 514, (ii) a first laser 516 that generates a first laser beam 516A (illustrated with short dashed arrow); (iii) a first lens assembly 518 that collimates the first laser beam 516A; (iv) a second laser 520 that generates a second laser beam 520A (illustrated with long dashed arrow); (v) a second lens assembly 22 that collimates the second laser beam 520A; (vi) a beam combiner 524 that combines the laser beams 516A, 520A to provide a combination beam 525 (illustrated with a thin, solid arrow); (vii) a first redirector 526 that directs the first laser beam 516A at the beam combiner 524; (viii) a second redirector 528; (ix) an optical assembly 532 that expands and collimates the combination beam 525 to provide the collimated output beam 512; and (x) a system controller 534 that controls one or more of the components of the laser assembly 510. It should be noted that the design and positioning of these components can be somewhat similar to the corresponding components described above and illustrated in FIG. 1A.

However, in the implementation of FIG. 5, (i) the second gain medium 520C is designed to directly generate the second laser beam 520A that has a polarization orientation that is different from the polarization orientation of the first laser beam 516A; (ii) a third redirector 529 cooperates with the second redirector 528 to direct the second laser beam 520A at the second combiner side 524B of the beam combiner 524; and (iii) the polarization rotator 30 (illustrated in FIG. 1A) is nolonger necessary. In this implementation, for example, the first laser 516 directly emits the first laser beam 516A having the first polarization state (orientation), and the second laser 520 directly emits the second laser beam 520A having the second polarization state (orientation) that is different from the first polarization state (orientation). For example, (i) the first gain medium 516C can be mounted epi-side down so that the first light beam 516A is linearly polarized with the electric field polarization oriented along the Y axis of FIG. 5; and (ii) the second gain medium 520C can be mounted so that the second light beam 520A is linearly polarized with the electric field polarization oriented along the X axis of FIG. 5. In this example, the gain mediums 516C, 520C can be mounted in a different orientation to change the orientation of the electric field polarization.

In this design, the first light beam 516A is reflected off of the beam combiner 524, and the second light beam 520A is transmitted through the beam combiner 524 to combine these beams.

While the particular laser assemblies as shown and disclosed herein is fully capable of obtaining the objects and providing the advantages herein before stated, it is to be understood that it is merely illustrative of the presently preferred embodiments of the invention and that no limitations are intended to the details of construction or design herein shown other than as described in the appended claims.

A complete listing of the claims in the present Application is as follows:

1. A laser assembly for generating an output beam, the laser assembly comprising:
a first laser that generates a first laser beam;
a second laser that generates a second laser beam;
a beam combiner that combines the first laser beam and the rotated second laser beam to form a combination beam; and
an optical assembly that expands and collimates the combination beam to provide the output beam that is accurately pointed in a far field, and pointing of the output beam is relatively insensitive to mechanical movement of the first laser, the second laser, and the beam combiner.

2. The laser assembly of claim 1 wherein the first laser beam has a first polarization state; wherein the second laser generates the second laser beam having the first polarization state; and the laser assembly includes a polarization rotator that rotates the polarization of second laser beam to a second polarization state.

3. The laser assembly of claim 1 wherein the first laser beam has a first polarization state; and wherein the second laser generates the second laser beam having a second polarization state that is different from the first polarization state.

4. The laser assembly of claim 1 wherein each laser is a mid-infrared laser and a wavelength of each laser beam is in a mid-infrared range.

5. The laser assembly of claim 4 wherein each mid-infrared laser is a tunable mid-infrared laser.

6. The laser assembly of claim 1 wherein the combination beam is directed along a combination axis, and wherein the optical assembly includes a first lens, a second lens, and a third lens that are spaced apart from each other, wherein the lenses of the optical assembly are coaxial with the combination axis.

7. The laser assembly of claim 6 wherein the first lens and the second lens form a beam expander that expands the combination beam, and the third lens is a projection lens that collimates the combination beam.

8. The laser assembly of claim 7 wherein wherein the first lens is a convex element that focuses the combination beam, the second lens is a diverging element that diverges the combination beam, and the third lens is a collimating element that collimates the combination beam to launch the output beam into free space.

9. The laser assembly of claim 7 wherein the optical assembly has a beam size magnification of at least one hundred.

10. The laser assembly of claim 1 further comprising a first lens assembly that collimates the first laser beam directed at the polarization beam combiner, and a second lens assembly that collimates the second laser beam directed at the polarization beam combiner.

11. A laser assembly for generating a mid-infrared output beam directed along an output axis, the laser assembly comprising:
a first laser that generates a first laser beam in a mid-infrared range having a first polarization state;
a first lens assembly that collimates the first laser beam;
a second laser that generates a second laser beam in the mid-infrared range;
a second lens assembly that collimates the second laser beam;
a polarization beam combiner that combines the collimated first laser beam and the collimated second laser beam to form a combination beam; and
an optical assembly that receives the combination beam and provides the mid-infrared output beam, the optical assembly including a first lens, a second lens, and a third lens that are spaced apart from each other; wherein the first lens is a convex element that focuses the combination beam, the second lens is a diverging element that diverges the combination beam, and the third lens is a collimating element that collimates the combination beam to launch the output beam into free space; wherein the lenses of the optical assembly are coaxial with, and spaced apart along, the output axis; wherein the first lens, the second lens and the third lens cooperate to minimize pointing errors of the output beam so that the output beam is accurately pointed in a far field.

12. The laser assembly of claim 11 wherein the second laser generates the second laser beam having the first polarization state; and the laser assembly includes a polarization rotator that rotates the polarization of the collimated second laser beam to a second polarization state.

13. The laser assembly of claim 11 wherein the second laser generates the second laser beam having a second polarization state that is different from the first polarization state.

14. The laser assembly of claim 11 wherein the first lens and the second lens form a beam expander, and the third lens is a projection lens that collimates the combination beam.

15. The laser assembly of claim 11 wherein the optical assembly has a beam size magnification of at least ten.

16. The laser assembly of claim 11 wherein the optical assembly has a beam size magnification of at least one hundred.

17. (canceled)

18. (canceled)

19. (canceled)

20. (canceled)

21. A method generating an output beam comprising:
generating a first laser beam;
collimating the first laser beam;
generating a second laser beam;
collimating the second laser beam;
combining the collimated first laser beam and the collimated second laser beam to form a combination beam; and
expanding and collimating the combination beam with an optical assembly to provide the output beam that is accurately pointed in a far field, and pointing of the output beam is relatively insensitive to temperature cycles and mechanical vibrations.

22. The method of claim 21 wherein the step of expanding and collimating includes the optical assembly having a first lens, a second lens, and a third lens that are spaced apart from each other along a combination axis; wherein the lenses of the optical assembly are coaxial with the combination axis; and wherein the first lens and the second lens form a beam expander that expands the combination beam, and the third lens is a projection lens that collimates the combination beam.

23. The method claim 22 wherein the step of expanding and collimating includes the first lens being a convex element that focuses the combination beam, the second lens being a diverging element that diverges the combination beam, and the third lens being a collimating element that collimates the combination beam to launch the output beam into free space along an output axis.

24. (canceled)

25. (canceled)

26. (canceled)

27. (canceled)

28. (canceled)

29. The method of claim 17 further comprising rotating the polarization of the collimated, second laser beam prior to the second laser beam being combined into the combination beam.
